(19) United States
(12) Patent Application Publication
(10) Pub. No.: US 2012/0181441 A1
(43) Pub. Date: Jul. 19, 2012

(54) RADIOGRAPHIC IMAGING APPARATUS, COMPUTER READABLE MEDIUM STORING RADIOGRAPHIC IMAGING PROGRAM, AND RADIOGRAPHIC IMAGING METHOD

(75) Inventor: Yoshihiro OKADA, Kanagawa (JP)

(73) Assignee: FUJIFILM CORPORATION, Tokyo (JP)

(21) Appl. No.: 13/338,280

(22) Filed: Dec. 28, 2011

(30) Foreign Application Priority Data
Jan. 14, 2011 (JP) 2011-006142

(51) Int. Cl. G01T 1/24; G01J 1/42

(52) U.S. Cl. 250/370.08; 250/394

(57) ABSTRACT

The present invention provides a radiographic imaging apparatus including: a plurality of pixels arrayed in a matrix, each of the pixels comprising: a photoelectric conversion element that generates and accumulates charges according to irradiation of radiation; a read-out switching element that read out the accumulated charges in response to a first control signal, and that outputs an electrical signal corresponding to the charges; and a shorting element that shorts the photoelectric conversion element in response to a second control signal.

### CROSS-REFERENCE TO RELATED APPLICATION

This application claims priority under 35 USC 119 from Japanese Patent Application No. 2011-006142, filed on Jan. 14, 2011 the disclosure of which is incorporated by reference herein.

### BACKGROUND OF THE INVENTION

1. Field of the Invention

The present invention relates to a radiographic imaging apparatus, a computer readable medium storing a radiographic imaging program, and a radiographic imaging method. The present invention relates particularly to a radiographic imaging apparatus, a computer readable medium storing radiographic imaging program, and a radiographic imaging method for imaging a medical radiographic image.

2. Description of the Related Art

A radiographic imaging apparatuses that perform radiographic imaging for medical diagnostic purposes are known. In such a radiographic imaging apparatus, radiation irradiated from a radiation irradiation device and that has passed through an investigation subject is detected, and a radiographic image is imaged. Radiographic imaging is performed in such a radiographic imaging apparatus by collecting and reading out charges generated according to the irradiation of radiation.

Such a radiographic imaging apparatus is provided with a radiation detection element for detecting radiation. As such a radiation detection element that is a radiation detection element including a photoelectric conversion element that generates charges when irradiated with radiation or illuminated with light that has been converted from the radiation, and a switching element that read out the accumulated charges that was generated in the photoelectric conversion element.

Sometimes remaining charges remains in the photoelectric conversion element after charges has been read out from the photoelectric conversion element. In particular, when a PIN photodiode using amorphous silicon as a photoelectric conversion layer is employed for such a photoelectric conversion element, a portion of the charges generated during photoelectric conversion may be trapped in defect levels in the amorphous silicon. The trapped charges accordingly remain as remaining charges.

Remaining charges resulting from imaging may influences a radiographic image when radiographic imaging is performed with remaining charges still remaining in the photoelectric conversion element, and is known as afterimage characteristics. There is therefore a requirement for technology to reduce the afterimage characteristics. A reset technique is described in Japanese Patent Application Laid-Open (JP-A) No. 10-189934 for suppressing variation due to afterimage characteristics of a photodiode. In this resetting technique a reverse bias voltage is applied to a photodiode using the output terminal of a switching element after data has been read out, and the photodiode is reset by applying a reverse bias voltage to the photodiode bias voltage after the data has been read out.

There is also a description in Japanese Patent No. 4500488 of a conventional technique in which a TFT for use in resetting a photoelectric conversion element is provided together with a dedicated reset line and reset power source for use in removing remaining charges. Remaining charges remaining in the photoelectric conversion element is eliminated to the reset line.

However, while the conventional technique of JP-A No. 10-189934 may reduce the afterimage characteristics provision, a dedicated read-out period for resetting the photodiode is required. Namely, since it is not possible to read out the charges from other pixels during the reset period, the read-out period per single frame is lengthened.

The conventional technique described in Japanese Patent No. 4500488 requires the dedicated reset line and reset power source for use in remaining charges elimination.

### SUMMARY OF THE INVENTION

The present invention provides a radiographic imaging apparatus, a computer readable storage medium storing a radiographic imaging program, and a radiographic imaging method, that may suppress the influence of afterimage characteristics, and may suppress the read-out period per single frame from becoming longer.

A first aspect of the present invention is a radiographic imaging apparatus including: a plurality of pixels arrayed in a matrix, each of the pixels including: a photoelectric conversion element that generates and accumulates charges due to irradiation of radiation; a read-out switching element that reads out the accumulated charges in response to a first control signal, and that outputs an electrical signal corresponding to the charges; and a shorting element that shorts the photoelectric conversion element in response to a second control signal.

When the read-out switching element has read the charges that was generated and accumulated according to the irradiation of radiation out from the photoelectric conversion element, not all the charges are read out and some remains, resulting in remaining charges. The amount of the remaining charges varies by pixel according to the amount of charges that has been accumulated in the photoelectric conversion element, namely according to the irradiated radiation.

In the first aspect of the present exemplary embodiment, the pixels arrayed in a matrix each include a shorting element that shorts the photoelectric conversion element in response to the second control signal. In the first aspect, a uniform amount of charges can be accumulated in the photoelectric conversion elements, not varying by pixel, by using the shorting elements to short the photoelectric conversion elements. Accordingly the first aspect of the present invention may suppress variation in the remaining charges amount by pixel, and may suppress the influence of afterimage characteristics.

According to the first aspect of the present invention, the shorting operation using the shorting element may be performed in sequence without providing a dedicated read-out period. Accordingly, the first aspect of the present invention may suppress the read-out period for all the pixels (a single frame) from increasing in length.

Consequently, the first aspect of the present invention may suppress the influence of afterimage characteristics, and may suppress the read-out period per single frame from lengthening.

A second aspect of the present invention, in the first aspect, the photoelectric conversion element may include: an upper electrode; a lower electrode; and a photoelectric conversion layer disposed between the upper electrode and the lower electrode, wherein the read-out switching element may be connected to the lower electrode, the shorting element may be a shorting switching element that shorts between the upper electrode and the lower electrode, and the radiographic imaging apparatus may further include: a bias line that applies a bias voltage to the upper electrode and that connects the upper electrode and the shorting switching element; a first control line in which the first control signal flows; a second control line in which the second control signal flows; and a signal line to which the electrical signal output from the read-out switching element is output.

A third aspect of the present invention, in the second aspect, the bias line may be disposed below the photoelectric conversion element with an insulating film interposed therebetween.

According to the above aspects of the present invention, charges can be read out by row using the read-out switching element, and shorting can be performed by row using the shorting switching element. Hence, in the above aspects of the present invention, the frame rate can be increased even further. Accordingly, the above aspects of the present invention may align the shorting periods of each of the photoelectric conversion element using the shorting switching elements, and may suppress variation of remaining charges due to the remaining charges.

A fourth aspect of the present invention, in the above aspects, the bias line may be disposed below the photoelectric conversion element with an insulating film interposed therebetween.

According to the fourth aspect of the present invention, the separation distance can be shortened between the electrode and the bias line for connecting the shorting switching element and the bias line. Accordingly, in the fourth exemplary embodiment of the present invention, a drop in manufacturing yield may be suppressed, and may suppress an increase in line capacitance.

A fifth aspect of the present invention, in the above aspects, the shorting switching element may be disposed below the photoelectric conversion element with an insulating film interposed therebetween.

According to the above aspect, the present invention may not cause the proportion of effective light collecting surface area relative to the pixel surface area to drop.

A sixth aspect of the present invention, in the above aspects, the photoelectric conversion element may be a PIN photodiode in which a P-type, an i-type and an N-type semiconductor layer are layered in this sequence.

A seventh aspect of the present invention is a computer readable storage medium storing a radiographic imaging program causing a computer to execute a process for radiographic imaging in the radiographic imaging apparatus of the first aspect, the process including: a first step that switches the read-out switching element to an OFF state, and that accumulates the charges, generated due to irradiation of radiation, in the photoelectric conversion element without shorting the photoelectric conversion element by using the shorting element; a second step, following the first step, that switches the read-out switching element to an ON state and that reads out the accumulated charges; a third step, following the second step, after placing the read-out switching element to an OFF state, that shorts the photoelectric conversion element by using the shorting element and that accumulates the charges in the photoelectric conversion element; and a fourth step, following the third step, that switches the read-out switching element in the ON state, without shorting the photoelectric conversion element by using the shorting element, and that discharges the charges that have been accumulated in the photoelectric conversion element.

An eighth aspect of the present invention is a radiographic imaging method for radiographic imaging in the radiographic imaging apparatus of the first aspect, the method including: a first step that switches the read-out switching element to an OFF state, and that accumulates the charges, generated due to irradiation of radiation, in the photoelectric conversion element without shorting the photoelectric conversion element by using the shorting element; a second step, following the first step, that switches the read-out switching element to an ON state and that read out the accumulated charges; a third step, following the second step, after placing the read-out switching element to an OFF state, that shorts the photoelectric conversion element by using the shorting element and that accumulates the charges in the photoelectric conversion element; and a fourth step, following the third step, that switches the read-out switching element in the ON state, without shorting the photoelectric conversion element by using the shorting element, and that discharges the charges that have been accumulated in the photoelectric conversion element.

A ninth aspect of the present invention, in the eighth aspect, the first step to the fourth step may be performed in sequence for the pixels that are disposed in the same row as each other.

According to the above aspect of the present invention, the frame rate may be further raised by performing each of the steps in sequence.

A tenth aspect of the present invention, in the ninth aspect, the fourth step may be performed in a period outside of the period during which the second step is performed.

When the fourth step is performed in the period during which the second step is performed, the charges discharged by the fourth step may be mixed with the charges that has been read out by the second step. Accordingly, in order to prevent the above mixture, the fourth step is preferably preformed in a period outside of the period during which the second step is performed.

An eleventh aspect of the present invention, in the above aspects, the fourth step may be performed in a period outside of the period during which the third step is being performed to the same row.

When the fourth step is performed on the same row as the third step is being performed, the charges discharged by the fourth step causes instability such as in the bias voltage source for supplying bias voltage to the bias line. Accordingly, the fourth step is preferably preformed in a period outside of the period during which the third step is performed to the same row.

As explained above, according to the above aspects of the present invention, the influence of afterimage characteristics may be suppressed and may suppress the period for reading out each frame from lengthening.

### BRIEF DESCRIPTION OF THE DRAWINGS

Exemplary embodiments of the present invention will be described in detail based on the following figures, wherein:

FIG. 1 is a configuration diagram illustrating the overall configuration of a radiographic imaging apparatus according to a present exemplary embodiment;

FIG. 2 is a plan view illustrating a configuration of a radiation detection element according to the present exemplary embodiment;

FIG. 3 is a cross-sectional view of the radiation detection element according to the present exemplary embodiment shown in FIG. 2, taken along line A-A;

FIG. 4 is a cross-sectional view of a radiation detection element according to the present exemplary embodiment shown in FIG. 2, taken along line B-B;

FIG. 5 is a schematic configuration diagram (equivalent circuit diagram) of a radiation detection element of the present exemplary embodiment;

FIG. 6 is a timing chart illustrating an operation to suppress influence of remaining charges in a radiographic imaging apparatus of the present exemplary embodiment; and

FIG. 7 is a timing chart illustrating an operation to suppress influence of remaining charges in a radiographic imaging apparatus of the present exemplary embodiment.

### DETAILED DESCRIPTION OF THE INVENTION

Explanation follows regarding an exemplary embodiment, with reference to the drawings.

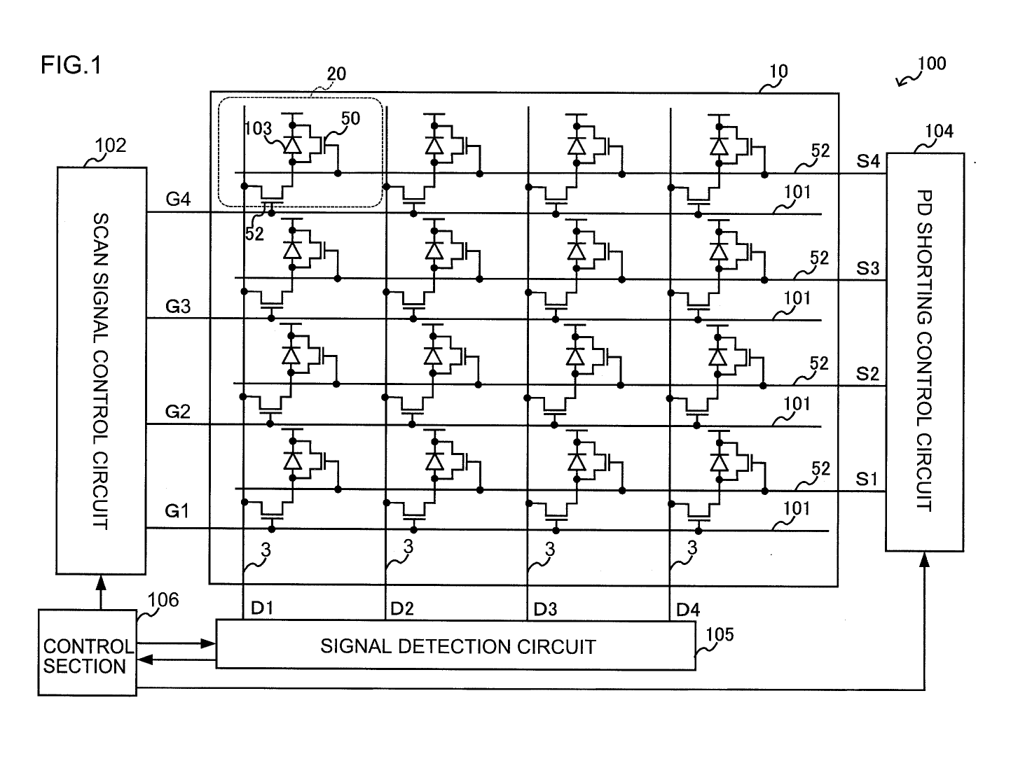

Explanation follows regarding a schematic configuration of a radiographic imaging apparatus of a present exemplary embodiment. FIG. 1 is a schematic diagram illustrating an overall configuration of a radiographic imaging apparatus 100 of the present exemplary embodiment. In the present exemplary embodiment, explanation will be given to a case in which the present invention is applied to an indirect-conversion-type radiation detection element 10 in which radiation such as X-rays is first converted into light, and the converted light is then converted into charge. In the present exemplary embodiment the radiographic imaging apparatus 100 is configured with the radiation detection element 10 of the indirect-conversion-type. Note that a scintillator for converting radiation into light is omitted in FIG. 1.

Plural pixels 20 are arrayed in a matrix in the radiation detection element 10. Each of the pixels 20 includes a sensor section 103 that receives light, generates charges and accumulates the generated charges, a TFT switch 4 that is a switching element for reading out the charges accumulated in the sensor section 103, and a TFT switch 50 that is a switching element for shorting the sensor section 103 in order to cause charges to accumulate. In the present exemplary embodiment, the sensor section 103 generates charges due to illumination of light that has been converted by the scintillator.

The plural pixels 20 are disposed, in a matrix, along a specific direction (the across direction in FIG. 1, referred to below as “row direction”), and a direction orthogonal to the row direction (the vertical direction in FIG. 1, referred to below as “column direction”). The array of the pixels 20 is simplified in FIG. 1, however an example is an array with 1024×1024 individual pixels 20 disposed respectively in the row direction and the column direction.

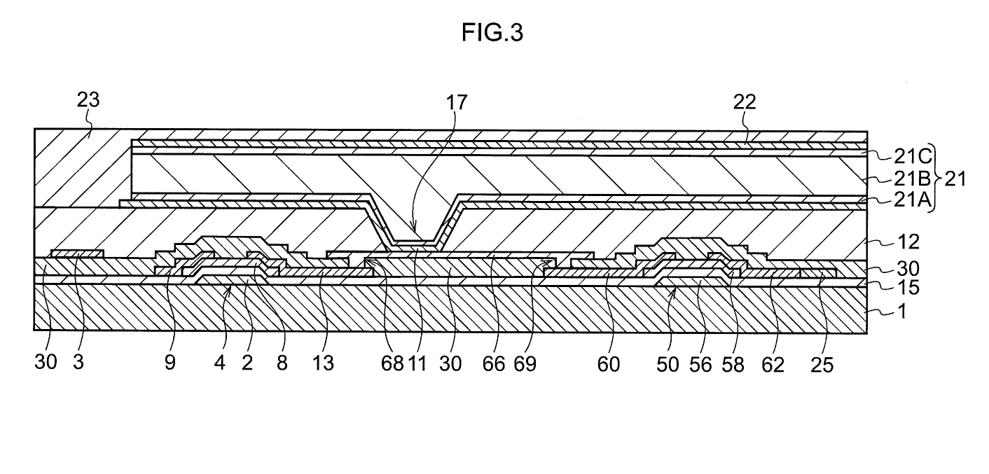

In the radiation detection element 10 plural scan lines 101 are provided on a substrate 1 (see FIG. 3) for switching the TFT switches 4 ON or OFF, and plural signal lines 3 are provided orthogonal to the scan lines 101 for reading out charges accumulated in the sensor sections 103. In the present exemplary embodiment, there is a single signal line 3 provided along the specific direction for each pixel row, and there is a single scan line 101 provided along the orthogonal direction for each pixel row. For example, when there are 1024×1024 individual pixels 20 respectively in the row direction and the column direction there are also 1024 signal lines 3 and 1024 scan lines 101 provided.

Plural scan lines 52 are provided parallel to the scan lines 101 in the radiation detection element 10 of the present exemplary embodiment for shorting the sensor sections 103 and causing the charges to be accumulated. In the present exemplary embodiment, there is a single scan line 52 provided for each pixel row. For example, when there are 1024×1024 individual pixels 20 respectively in the row direction and the column direction, there are also 1024 scan lines 52 provided.

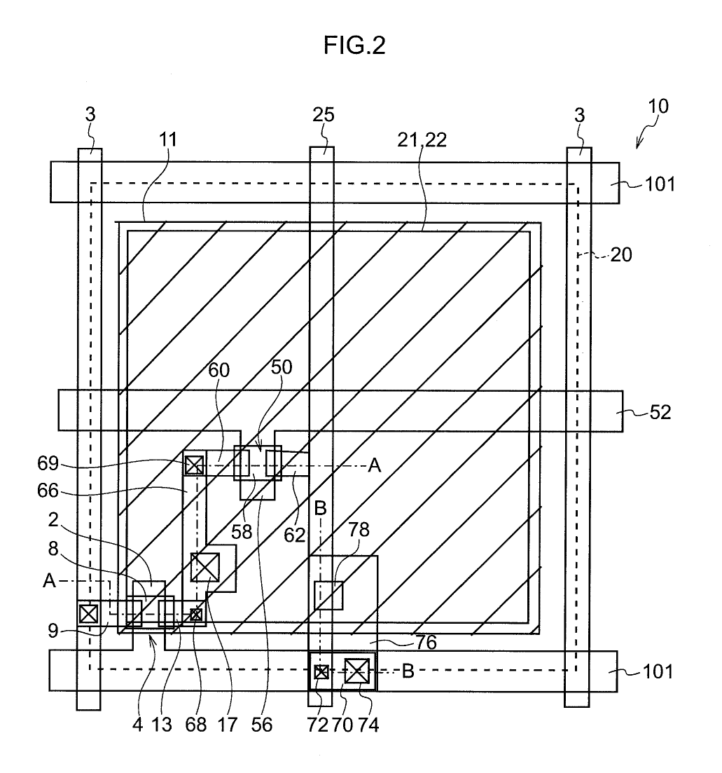

Bias lines 25, are provided in parallel to each of the signal lines 3 in the radiation detection element 10 (see FIG. 2). The first ends and second ends of the bias lines 25 are connected together in parallel, with the first ends connected to a power source (not shown in the drawings) that supplies a specific bias voltage. The sensor sections 103 are connected to the bias lines 25 and are applied with a bias voltage through the bias lines 25.

Control signals for switching each of the TFT switches 4 flow in the scan lines 101. Each of the TFT switches 4 is switched by the control signals flowing in each of the scan lines 101.

Electrical signals corresponding to charges that has accumulated in each of the pixels 20 flow in the signal lines 3 depending on the switching state of each of the TFT switches 4 of the pixels 20. More specifically, switching ON the TFT switch 4 of the pixel 20 connected to a given signal line 3 results in an electrical signal flowing in the given signal line 3 corresponding to the charges that was accumulated in the pixel 20.

The signal lines 3 are connected to a signal detection circuit 105 for detecting the electrical signals flowing out of each of the signal lines 3. The scan lines 101 are connected to a scan signal control circuit 102 for outputting to each of the scan lines 101 control signals for switching the TFT switches 4 ON or OFF. The scan lines 52 are each connected to a PD shorting control circuit 104 for outputting to each of the scan lines 52 control signals for switching the TFT switches 50 ON or OFF. In FIG. 1, simplification has been made to a single of the signal detection circuit 105, a single of the scan signal control circuit 102, and a single of the PD shorting control circuit 104. However, for example, plural signal detection circuits 105, scan signal control circuits 102 and PD shorting control circuits 104 are provided, each connected to a specific number (for example 256) of the signal lines 3, the scan lines 101 or the scan lines 52. For example, when there are 1024 lines provided for the signal lines 3, the scan lines 101 and the scan lines 52, four of the scan signal control circuits 102 are provided connected one for every 256 of the scan lines 101, four of the signal detection circuits 105 are provided connected one for every 256 of the signal lines 3, and four of the PD shorting control circuits 104 are provided connected one for every 256 of the scan lines 52.

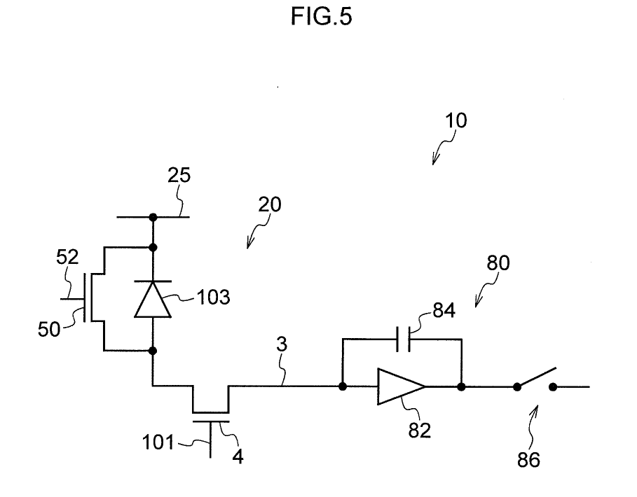

The signal detection circuit 105 is installed with a charge amplifier 80 (see FIG. 5) for each of the signal lines 3 to amplify input electrical signals. In the signal detection circuit 105, each of the electrical signals input from the signal lines 3 is amplified by using the charge amplifier 80 and output as image data.

A control section 106 is connected to the signal detection circuits 105, the scan signal control circuits 102 and the PD shorting control circuits 104. The control section 106 performs specific process, such as noise reduction process, on the digital signals converted in each of the signal detection circuit 105. Further, the control section 106 outputs a control signal to each of the signal detection circuits 105 instructing a timing for signal detection, outputs to each of the scan signal control circuits 102 a control signal instructing a timing for output of scan signals, and outputs a control signal to each of the PD shorting control circuits 104 instructing a timing for output of shorting signals.

The control section 106 in the present exemplary embodiment is configured by a microcomputer including a Central Processing Unit (CPU), ROM and RAM, and a nonvolatile storage section such as flash memory. The control section 106 then generates an image expressing the radiation that was irradiated based on the image data that has been subjected to the above specific process.

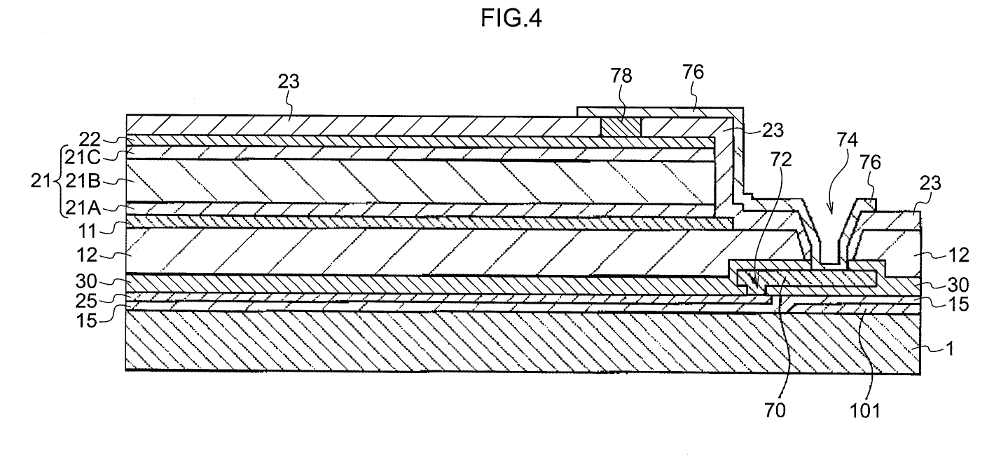

FIG. 2 is a plan view illustrating a structure of one of the pixels 20 of the indirect conversion type radiation detection element 10 according of the present exemplary embodiment. FIG. 3 is a cross-sectional view of a pixel 20 employed in radiographic imaging of FIG. 2, taken along line A-A. FIG. 4 is a cross-sectional view of a radiographic imaging pixel 20 employed in radiation detection of FIG. 2, taken along line B-B.

As shown in FIG. 3, each pixel 20 of the radiation detection element 10 has a scan line 101 (see FIG. 2) and a gate electrode 2 of the TFT switch 4, a scan line 52 (see FIG. 2) and a gate electrode 56 of the TFT switch 50 formed on the insulating substrate 1 made from a material such as alkali-free glass. The scan line 101 and the gate electrode 2 are connected together (see FIG. 2), and the scan line 52 and the gate electrode 56 are connected together (see FIG. 2). The wiring layer in which the scan lines 101, the gate electrodes 2, the scan lines 52 and the gate electrodes 56 are formed (this wiring layer is referred to below as the first signal wiring layer) is formed with Al and/or Cu, or with a layered film with a main component of Al and/or Cu, however there is no limitation thereto.

An insulation film 15 is formed on one face of the first signal wiring layer, and portions of the insulation film 15 above the gate electrodes 2 act as a gate insulation film of the TFT switches 4. The portion of the insulation film 15 above the gate electrodes 56 acts as a gate insulation film in the TFT switches 50. The insulation film 15 is formed, for example, from SiNₓ by, for example, Chemical Vapor Deposition (CVD) film forming.

An island shape of a semiconductor active layer 8 is formed above the insulation film 15 on the gate electrode 2. The semiconductor active layer 8 is a channel portion of the TFT switch 4 and is, for example, formed from an amorphous silicon film. Similarly, an island shape of a semiconductor active layer 58 is formed above the insulation film 15 on the gate electrode 56. The semiconductor active layer 58 is a channel portion of the TFT switch 50 and is, for example, formed from an amorphous silicon film

A source electrode 9 and a drain electrode 13 of the TFT switch 4 are formed in a layer above the above portions of the TFT switch 4. An electrode 60 and an electrode 62 of the TFT switch 50, and the bias line 25 also similarly formed in a layer above the above portions of the TFT switch 50. The electrode 62 is connected to the bias line 25. The wiring layer in which the source electrode 9, the drain electrode 13, the electrode 60, the electrode 62 and the bias line 25 are formed (referred to below as the second wiring layer) is formed with Al and/or Cu, or with a layered film with a main component of Al and/or Cu. However, the material of the second signal wiring layer is not limited thereto. An impurity doped semiconductor layer (not shown in the drawings) is formed from a material such as impurity doped amorphous silicon between the semiconductor active layer 8 and both the source electrode 9 and the drain electrode 13, and between the semiconductor active layer 58 and both the electrode 60 and the electrode 62. The TFT switch 4 employed for switching and the TFT switch 50 employed for shorting are configured as described above. Note that the source and drain of the TFT switch 4 and the TFT switch 50 are reversed according to the polarity of the charges collected and accumulated by a bottom electrode 11, described later.

A TFT protection layer 30 to protect the TFT switches 4, the TFT switches 50, and the bias lines 25 is formed covering the second signal wiring layer over substantially the whole of the region provided with the pixels 20 on the substrate 1 (substantially the entire region). The TFT protection layer 30 is formed, for example, from SiNₓ using, for example, CVD film forming.

The signal lines 3 are formed on the TFT protection layer 30. The signal line 3 is connected to the source electrode 9 (see FIG. 2).

A contact layer 66 is formed on the TFT protection layer 30. The contact layer 66 is connected to the drain electrode 13 of the TFT switch 4 through a contact hole 68 and the contact layer 66 is connected to the electrode 60 of the TFT switch 50 through a contact hole 69.

A coated interlayer insulation film 12 is formed on the TFT protection layer 30 and the contact layer 66. The interlayer insulation film 12 is formed by a low permittivity (specific permittivity εr=2 to 4) photosensitive organic material (examples of such materials include positive working photosensitive acrylic resins materials with a base polymer formed by copolymerizing methacrylic acid and glycidyl methacrylate, mixed with a naphthoquinone diazide positive working photosensitive agent) at a film thickness of 1 μm to 4 μm.

In the radiation detection element 10 according to the present exemplary embodiment, inter-metal capacitance between metal disposed in the layers above the interlayer insulation film 12 and below the interlayer insulation film 12 is suppressed to be small by the interlayer insulation film 12. Generally such materials also function as a flattening layer, exhibiting an effect of flattening out steps in the layers below. In the radiation detection element 10 of the present exemplary embodiment, a contact hole 17 is formed at a position corresponding to the interlayer insulation film 12 and the contact layer 66 of the TFT protection layer 30.

The bottom electrode 11 of the sensor section 103 is formed above the interlayer insulation film 12 to cover the pixel region while also filling the contact hole 17. The bottom electrode 11 is connected to the drain electrode 13 of the TFT switch 4 and to the electrode 60 of the TFT switch 50. When the thickness of a semiconductor layer 21 is about 1 μm there are substantially no limitations to the material of the bottom electrode 11, as long as it is an electrically conductive material. The bottom electrode 11 may therefore be configured by a conductive metal such as an aluminum material or ITO.

However, when the film thickness of the semiconductor layer 21 is thin (about 0.2 μm to 0.5 μm), since there is insufficient light absorption in the semiconductor layer 21, an alloy or layered film with a main component of a light blocking metal is preferably employed for the bottom electrode 11, in order to prevent an increase in leak current occurring due to light illumination onto the TFT switch 4.

The semiconductor layer 21 functioning as a photodiode is formed over the bottom electrode 11. In the present exemplary embodiment a PIN structure photodiode is employed for the semiconductor layer 21, with a n+layer, i layer, and p+layer (n+amorphous silicon, amorphous silicon, p+amorphous silicon), configured as layers of an n+layer 21A, an i layer 21B, and a p+layer 21C, in sequence from the lower layer. The i layer 21B generates charges (pairs of a free electron and a free hole) due to illumination of light. The n+layer 21A and the p+layer 21C function as contact layers, electrically connecting the i layer 21B to the bottom electrode 11 and to upper electrode 22, described below.

Individual upper electrodes 22 are respectively formed above the semiconductor layers 21. The upper electrodes 22 employ a material with high light transmissivity such as, for example, ITO or Indium Zinc Oxide (IZO). The radiation detection element 10 of the present exemplary embodiment is configured with the sensor sections 103 each configured to include the upper electrode 22, the semiconductor layer 21 and the bottom electrode 11.

A coated intermediate insulation film 23 is formed over the intermediate insulation film 12, the semiconductor layer 21 and the upper electrode 22, so as to cover each of the semiconductor layers 21.

Bias lines 25 are formed over the intermediate insulation film 23 with Al and/or Cu, or with an alloy or layered film with a main component of Al and/or Cu. The bias lines 25 are each formed with a contact pad 27 in the vicinity of the opening 27A and are each electrically connected to the upper electrode 22 through the opening 27A in the intermediate insulation film 23.

As shown in FIG. 4, a cross-sectional view along line B-B of FIG. 2, a contact layer 70 is formed to a portion over the scan line 101 and the bias line 25, with the insulation film 15 interposed therebetween and the contact layer 70 making contact with the bias line 25 through a contact hole 72.

A contact line 76 is formed between portion over of the intermediate insulation film 23 and a portion over the contact layer 70. The contact line 76 is connected to the contact layer 70 by a contact hole 74, and is also connected to the upper electrode 22 through a contact 78.

The upper electrode 22 and the bias line 25 are in a connected state in the radiation detection element 10 according to the present exemplary embodiment.

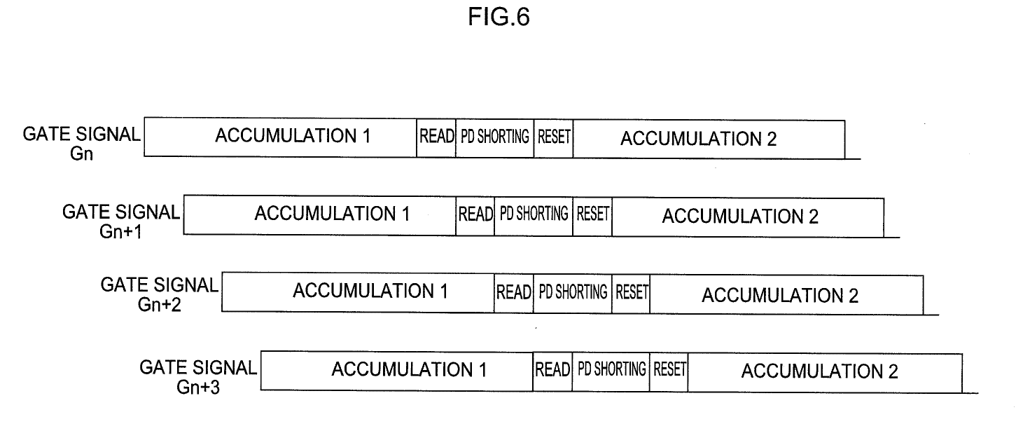

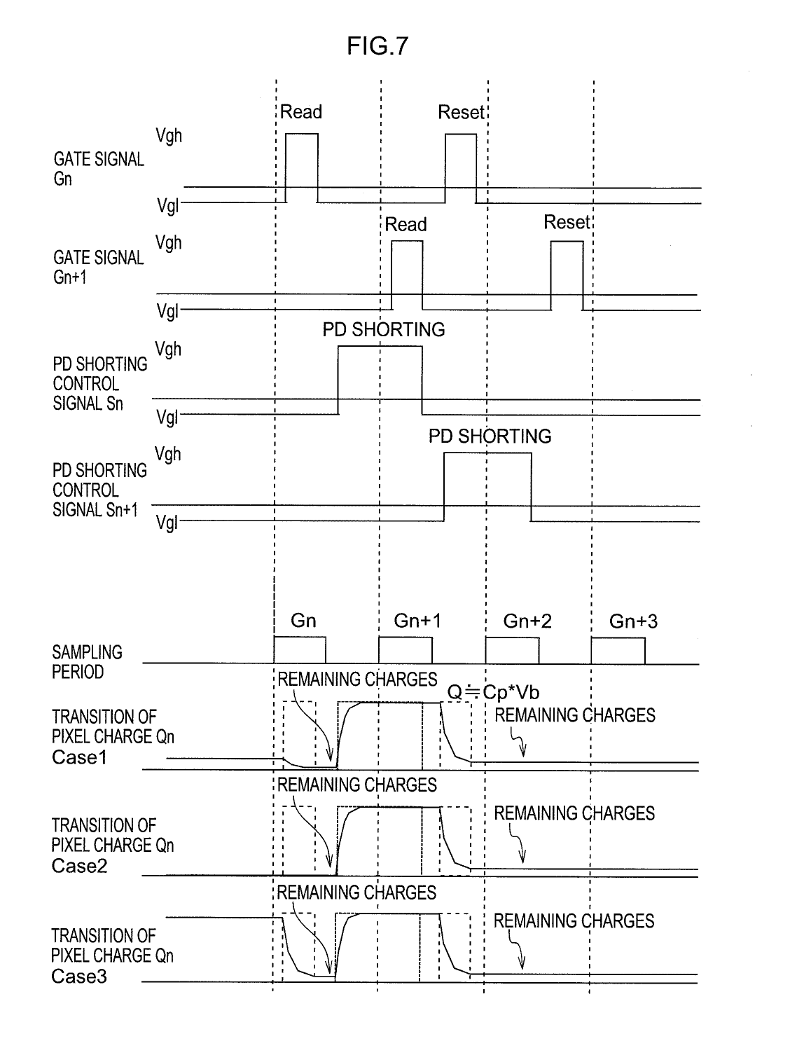

Detailed explanation follows regarding operation to suppress the influence of remaining charges on radiographic imaging in the radiation detection element 10 of the present exemplary embodiment. FIG. 5 is a schematic configuration diagram (equivalent circuit diagram) of an example of the radiation detection element 10 of the present exemplary embodiment. FIG. 6 and FIG. 7 are timings charts illustrating examples of operation to suppress influence of remaining charges in the present exemplary embodiment.

As described above, in the radiation detection element 10 of the present exemplary embodiment, each of the pixels 20 is configured to include the sensor section 103, the TFT switch 4 and the TFT switch 50. The TFT switches 50 has functionality for shorting between the input side and the output side of the sensor section 103. In the radiation detection element 10 of the present exemplary embodiment, each TFT switch 50 is connected to the lower electrode of the sensor section 103, and also connected to the upper electrode of the sensor section 103 through the bias line 25. Each of The TFT switch 50 is also connected to the scan line 52, and is controlled ON or OFF by a control signal output from the PD shorting control circuit 104 to the scan line 52.

In the radiation detection element 10 of the present exemplary embodiment, the charge amplifiers 80 are provided for each of the signal lines 3 (each of the columns of pixels 20). Namely, the signal detection circuit 105 of the radiation detection element 10 is configured with plural of the charge amplifiers 80, with this being the same number as the number of the signal lines 3 of the radiation detection element 10.

Each of the charge amplifiers 80 is configured including an amplifier 82 such as an operational amplifier and a capacitor 84 connected to the amplifier 82.

In the charge amplifier 80, charges (an electrical signal) are read by the TFT switch 4 of the pixel 20, and the charges read out are accumulated in the capacitor 84, such that the voltage value output from the amplifier 82 increases according to the charge amount that was accumulated. When a sample and hold switch 86 in the ON state, the electrical voltage output from the amplifier 82 (the electrical signal that is charge data), is converted from an analogue signal into a digital signal by an analogue-to-digital converter (ADC) (not shown in the drawings) and is output to the control section 106.

In the radiation detection element 10 of the present exemplary embodiment, each of the operations for radiographic image imaging is performed for each row of pixels 20 (each of the scan lines 101). First, with the TFT switches 4 and the TFT switches 50 in the OFF state, charges in the sensor section 103 that are generated in the semiconductor layer 21 due to irradiation of the radiation are accumulated in the bottom electrodes 11 (see “accumulation 1” in FIG. 6). The amount of charges generated here in the sensor sections 103 differs according to the radiation dose irradiated. Then, the TFT switches 4 are placed in the ON state, and charges are read out from the sensor sections 103 (see READ in FIG. 6 and FIG. 7). However when this occurs, the charges generated in the sensor sections 103 are not completely read out, and some remaining charges remains in the sensor sections 103. However, the remaining charges amount also differs when the charge amount generated in the sensor sections 103 differ from each other. Namely, a state in which the remaining charge amount varies for each pixel 20 occurs.

Then, the TFT switches 4 are placed in the OFF state, and the TFT switches 50 are placed in the OFF state, thereby shorting the sensor sections 103. Shorting the sensor section s103 irrespective of whether there is radiation irradiated thereon results in a bias voltage being applied and charges being generated in the sensor sections 103. In the present exemplary embodiment, shorting is performed until a saturated state charge amount Q (see FIG. 7, Q≈Cp×Vb, Cp: capacity of sensor section 103, Vb: bias voltage value) has been accumulated, such that the same amount of charges are accumulated in all of the sensor sections 103 irrespective of which pixel 20 is referred to.

When shorting of the sensor sections 103 (charge accumulation) is finished the TFT switches 50 are placed in the OFF state and the TFT switches 4 are placed in the ON state, thereby resetting sensor sections 103 (see “reset” in FIG. 6 and FIG. 7). The charges accumulated in the sensor sections 103 are discharged by the reset operation. After the reset operation, in order to re-perform radiographic imaging charges according to the radiation that has been irradiated is generated and accumulated in the sensor sections 103 (see “accumulation 2” of FIG. 6).

Not all of the charges accumulated in the sensor sections 103 are discharged from the sensor sections 103 even though the above reset operation is performed, and some remaining charges remains. However in contrast to “accumulation 1 shown” in FIG. 6, due to the charges accumulated in the sensor sections 103 being constant (saturated), the remaining charges amounts are aligned with each other as a constant amount that does not vary by pixel 20. Accordingly, despite there being some such remaining charges, variation in the afterimage characteristics of each of the pixels 20 may be suppressed. Accordingly, influence of the afterimage characteristics may be suppressed in “accumulation 2” of FIG. 6.

A more detailed explanation follows with respect to FIG. 7. In the sensor sections 103, the charges generated in the semiconductor layer 21 according to the irradiated radiation are accumulated in the bottom electrodes 11 (see “accumulation 1” of FIG. 6). Transitions in the pixel charge Qn illustrated in FIG. 7 relate to: Case 1, circumstances under which an intermediate radiation dose has been irradiated and an intermediate amount of charges has been accumulated; Case 2, circumstances under which there is no or substantially no charges has been accumulated due to no radiation or substantially no radiation having been irradiated; and Case 3, circumstances under which a high radiation has been irradiated and charges has been accumulated up to a saturated state of the sensor section 103.

In order to read out the accumulated charge, the sample and hold switch 86 is switched to the ON state one line at a time (see “sampling period” in FIG. 7). The gate signal Gn then becomes Vgh, and the TFT switches 4 of one row's worth of the pixels 20 that are connected to the scan line 101 to which the gate signal Gn is input are placed in the ON state, and the charges accumulated in the sensor sections 103 are read out (see “read” in FIG. 7). When the TFT switches 4 are placed in the OFF state and the read operation is finished, the sample and hold switch 86 is then placed in the OFF state, and the sampling period ends. The remaining charges remaining in the sensor sections 103 after the charges read-out operation differs according to the amount of charges that was accumulated. Namely, there is a state with variation in the remaining charges amount across the pixels 20 at this point in the operation. As shown in the illustrated transitions in the pixel charge Qn in FIG. 7, the remaining charges amount in this state is a lot in Case 3 and a little in Case 2.

A PD shorting control signal Sn becomes Vgh in order to short the sensor sections 103, and the TFT switches 50 of the single row of pixels 20 connected to the scan line 52 to which the PD shorting control signal Sn is input are accordingly placed in an ON state. PD shorting operation is thereby performed with charges being accumulated in the sensor sections 103. In the present exemplary embodiment, after achieving a state in which charges has been accumulated of a specific amount for all of the pixels (a saturated state in the present exemplary embodiment), the TFT switches 50 are then placed in the OFF state and PD shorting operation is ended.

In the present exemplary embodiment, during the PD shorting operation for a given line, read-out operation to read out the charges accumulated according to irradiated radiation is executed on the next line of pixels 20 or other pixels 20. When the read-out operation on the next line of pixels 20 or other pixels 20 is finished, and after the sampling period has finished for the given line, namely, in a state in which read-out operation of charges accumulated according to irradiated radiation is not being performed for any of the pixels 20 (charge data is not being output), the gain signal Gn is again made Vgh, the TFT switches 4 are placed in the ON state, and charges accumulated in the sensor sections 103 due to the PD shorting operation is removed, thereby resetting the charges in the sensor sections 103 (RESET in FIG. 7) for the given line.

According to the reset operation the pixel charge Qn transitions as shown in FIG. 7, and the remaining charges becomes a similar amount in all of the cases from Case 1 to Case 3.

Consequently, variation in the afterimage characteristics of each of the pixels 20 may be suppressed, and the influence of afterimage characteristics may be suppressed.

In the present exemplary embodiment during reset operation on a given line of pixels 20 the PD shorting operation is being executed on the next line of pixels 20 or other pixels 20. Preferably configuration is made such that the PD shorting operation and the reset operation for the same line are not performed at the same time. When the PD shorting operation and reset operation overlap with each other, charges flows from the bias line 25 to the amplifier 82, causing an unstable state of the bias voltage and the amplification power source (both not shown in the drawings). Therefore, it is preferable for the PD shorting operation and the reset operation not to overlap with each other.

In the present exemplary embodiment, the reset operation is performed in a period that does not overlap with the sampling period (a charge transmission period of the amplifier 82). Accordingly, Charge data removed by the reset operation may be prevented from mixing with charges being read out by the read-out operation.

The frame rate may also be further increased by performing the reset operation in the charge transmission period of the amplifier 82 while performing the PD shorting operation on the next line as described above.

In the present exemplary embodiment, after reading out charges accumulated in the sensor sections 103, the sensor sections 103 are then reset by performing the shorting operation on the sensor sections 103, however it is not essential to read out the charges accumulated in the sensor sections 103. Accordingly, for the purpose of suppressing remaining charges amount variation configuration may be made such that shorting and reset operation of the sensor sections 103 is performed without reading out charges accumulated in the sensor sections 103. Namely, with the TFT switches 4 and the TFT switches 50 in the OFF state, the charges generated in the semiconductor layer 21 of the sensor section 103 according to the irradiated radiation is accumulated in the bottom electrode 11. Then, with the TFT switches 4 in the OFF state and the TFT switches 50 placed in the ON state, the sensor sections 103 are shorted, and the charge amount Q of the saturated amount is accumulated in the sensor sections 103 irrespective of which pixel 20. When the shorting operation of the sensor sections 103 is finished, the TFT switches 50 are placed in the OFF state and the TFT switches 4 placed in the ON state, discharging the charges from and resetting the sensor sections 103.

In the radiographic imaging apparatus 100 of the present exemplary embodiment, each of the operations described above is performed in sequence by row, and the length of time for reading out a single frame may be suppressed from being lengthened, since this does not entail provision of a separate read-out period to discharge the charges accumulated by the shorting operation.

In the radiographic imaging apparatus 100 of the present exemplary embodiment, a drop in manufacturing yield may be prevented, since configuration may be made without entailing the provision of a separate power source to use on the TFT switches 50 and without provision of separate dedicated wiring lines for discharging charges from the TFT switches 50.

In the present exemplary embodiment, the TFT switches 50 are provided at portions below the semiconductor layer 21 that act as photodiodes, hence the effective light collection surface area may also be prevented from falling as a proportion of the pixel 20 surface area.

In the present exemplary embodiment due to providing the bias lines 25 at portions below the semiconductor layer 21 where the TFT switches 50 are provided, the connection portions between the bias lines 25 and the TFT switches 50 may be made short, enabling manufacturing yield to be raised.

In the present exemplary embodiment, a case in which the shorting operation and the reset operation are performed a single row at a time, has been described. However, configuration may be made in which some or all of these operations are performed several rows at a time. For example, after the shorting operation has been performed by single row, the reset operation may be performed for several rows at the same timing. In such cases, for example, when performing successive image of radiographic images such as for a video image, since radiation irradiation is continuous, charges are generated by radiation irradiation as soon as the sensor section 103 are placed in a floating state, and variation in the charge amounts is a cause of variation in remaining charges amount. Consequently, in order to suppress variation in the remaining charges amount, the duration from performing the shorting operation to performing the reset operation is preferably made as short as possible. Preferably these operations are executed with the optimum number of rows at a time, with the optimum number of rows obtained according to factors such as the capacity of the sensor sections 103 and the charge accumulation period.

The configurations and operation of the radiographic imaging apparatus 100, the radiation detection element 10 and the like explained in the present exemplary embodiments are merely examples. Obviously various changes are possible according to circumstances within a scope not departing from the spirit of the present invention.

There is no particular limitation to the radiation employed in the present exemplary embodiment of the present invention, and radiation such as X-rays and gamma rays is appropriately employed.

What is claimed is:

1. A radiographic imaging apparatus comprising:
a plurality of pixels arrayed in a matrix, each of the pixels comprising:
a photoelectric conversion element that generates and accumulates charges due to irradiation of radiation;
a read-out switching element that reads out the accumulated charges in response to a first control signal, and that outputs an electrical signal corresponding to the charges; and
a shorting element that shorts the photoelectric conversion element in response to a second control signal.

2. The radiographic imaging apparatus of claim 1,
wherein the photoelectric conversion element comprises:
an upper electrode;
a lower electrode; and
a photoelectric conversion layer disposed between the upper electrode and the lower electrode,
wherein the read-out switching element is connected to the lower electrode, the shorting element is a shorting switching element that shorts between the upper electrode and the lower electrode, and
the radiographic imaging apparatus further comprises:
a bias line that applies a bias voltage to the upper electrode and that connects the upper electrode and the shorting switching element;
a first control line in which the first control signal flows;
a second control line in which the second control signal flows; and
a signal line to which the electrical signal output from the read-out switching element is output.

3. The radiographic imaging apparatus of claim 2, wherein the shorting switching elements of pixels that are in the same row are connected to the first control line, and the shorting switching elements of the pixels that are in the same row are connected to the second control line.

4. The radiographic imaging apparatus of claim 2, wherein the bias line is disposed below the photoelectric conversion element with an insulating film interposed therebetween.

5. The radiographic imaging apparatus of claim 2, wherein the shorting switching element is disposed below the photoelectric conversion element with an insulating film interposed therebetween.

6. The radiographic imaging apparatus of claim 1, wherein the photoelectric conversion element is a PIN photodiode in which a P-type, an i-type and an N-type semiconductor layer are layered in this sequence.

7. A computer readable storage medium storing a radiographic imaging program causing a computer to execute a process for radiographic imaging in the radiographic imaging apparatus of claim 1, the process comprising:
a first step that switches the read-out switching element to an OFF state, and that accumulates the charges, generated due to irradiation of radiation, in the photoelectric conversion element without shorting the photoelectric conversion element by using the shorting element;
a second step, following the first step, that switches the read-out switching element to an ON state and that reads out the accumulated charges;
a third step, following the second step, after placing the read-out switching element to an OFF state, that shorts the photoelectric conversion element by using the shorting element and that accumulates the charges in the photoelectric conversion element; and
a fourth step, following the third step, that switches the read-out switching element in the ON state, without shorting the photoelectric conversion element by using the shorting element, and that discharges the charges that have been accumulated in the photoelectric conversion element.

8. A radiographic imaging method for radiographic imaging in the radiographic imaging apparatus of claim 1, the method comprising:
a first step that switches the read-out switching element to an OFF state, and that accumulates the charges, generated due to irradiation of radiation, in the photoelectric conversion element without shorting the photoelectric conversion element by using the shorting element;
a second step, following the first step, that switches the read-out switching element to an ON state and that read out the accumulated charges;
a third step, following the second step, after placing the read-out switching element to an OFF state, that shorts the photoelectric conversion element by using the shorting element and that accumulates the charges in the photoelectric conversion element; and
a fourth step, following the third step, that switches the read-out switching element in the ON state, without shorting the photoelectric conversion element by using the shorting element, and that discharges the charges that have been accumulated in the photoelectric conversion element.

9. The radiographic imaging method of claim 8, wherein the first step to the fourth step are performed in sequence for the pixels that are disposed in the same row as each other.

10. The radiographic imaging method of claim 9, wherein the fourth step is performed in a period outside of the period during which the second step is performed.

11. The radiographic imaging method of claim 9, wherein the fourth step is performed in a period outside of the period during which the third step is being performed to the same row.
